(19) United States
(12) Patent Application Publication
(10) Pub. No.: US 2025/0142841 A1
(43) Pub. Date: May 1, 2025

(54) SEMICONDUCTOR STRUCTURE AND MANUFACTURING METHOD THEREOF

(71) Applicant: United Microelectronics Corp., Hsinchu (TW)

(72) Inventor: Shin-Hung Li, Nantou County (TW)

(73) Assignee: United Microelectronics Corp., Hsinchu (TW)

(21) Appl. No.: 18/515,299

(22) Filed: Nov. 21, 2023

(30) Foreign Application Priority Data
Oct. 27, 2023 (CN) 202311413621.8

(51) Int. Cl. H01L 29/94; H01L 29/66; H01L 29/786

(52) U.S. Cl. CPC H10D 1/66; H10D 30/031; H10D 30/67

(57) ABSTRACT

Provided are a semiconductor structure and a manufacturing method thereof. The semiconductor structure includes a first electrode, a second electrode, an insulating layer, a channel layer, a gate dielectric layer, a source electrode and a drain electrode. The first electrode is disposed on a substrate. The second electrode is disposed on the first electrode. The insulating layer is disposed between the first electrode and the second electrode. The channel layer is disposed on the second electrode. The gate dielectric layer is disposed between the channel layer and the second electrode. The source electrode is electrically connected to the first electrode and the channel layer. The drain electrode is electrically connected to the channel layer.

### CROSS-REFERENCE TO RELATED APPLICATION

This application claims the priority benefit of China application serial no. 202311413621.8, filed on Oct. 27, 2023. The entirety of the above-mentioned patent application is hereby incorporated by reference herein and made a part of this specification.

### BACKGROUND

### Technical Field

The present invention relates to a semiconductor structure, and in particular to a semiconductor structure including a capacitor and a thin-film transistor (TFT).

### Description of Related Art

With the expansion of application fields and the increase in transmitted information content, the technologies and types of displays have gradually become diversified, and consumers' requirements for displays have also been increased. In some displays, a thin-film transistor and a capacitor may be included. Generally speaking, the thin-film transistor and the capacitor are disposed on the substrate and separated from each other, and are electrically connected to each other through the circuit layer(s). As a result, more layout area is occupied, causing the size of the display to be unable to be reduced. In addition, in some displays, the thin-film transistor and capacitor are stacked on the substrate, and the thin-film transistor and the capacitor are electrically connected to each other through a circuit structure. However, this technical approach results in the inability to effectively reduce the thickness of the display.

### SUMMARY

The present invention provides a semiconductor structure, wherein a capacitor and a thin-film transistor are stacked on a substrate, and the upper electrode of the capacitor may be used as the gate of the thin-film transistor.

The present invention provides a manufacturing method of a semiconductor structure, wherein the semiconductor structure includes a capacitor and a thin-film transistor formed on a substrate, and the upper electrode of the capacitor may be used as the gate of the thin-film transistor.

The semiconductor structure of the present invention includes a first electrode, a second electrode, an insulating layer, a channel layer, a gate dielectric layer, a source electrode and a drain electrode. The first electrode is disposed on a substrate. The second electrode is disposed on the first electrode. The insulating layer is disposed between the first electrode and the second electrode. The channel layer is disposed on the second electrode. The gate dielectric layer is disposed between the channel layer and the second electrode. The source electrode is electrically connected to the first electrode and the channel layer. The drain electrode is electrically connected to the channel layer.

In an embodiment of the semiconductor structure of the present invention, the second electrode and the insulating layer expose a portion of the first electrode.

In an embodiment of the semiconductor structure of the present invention, the channel layer and the gate dielectric layer expose a portion of the second electrode.

In an embodiment of the semiconductor structure of the present invention, the semiconductor structure further includes a cap layer covering the first electrode, the insulating layer, the second electrode, the gate dielectric layer and the channel layer.

In an embodiment of the semiconductor structure of the present invention, a material of the cap layer includes silicon nitride (SiN), silicon carbonitride (SiCN) or silicon oxynitride (SiON).

In an embodiment of the semiconductor structure of the present invention, the second electrode is electrically connected to a transistor disposed at the substrate.

In an embodiment of the semiconductor structure of the present invention, the semiconductor structure further includes a buffer layer disposed between the substrate and the first electrode.

In an embodiment of the semiconductor structure of the present invention, a material of the buffer layer includes SiN, SiCN or SiON.

In an embodiment of the semiconductor structure of the present invention, the source electrode and the drain electrode are disposed on the channel layer.

In an embodiment of the semiconductor structure of the present invention, the source electrode and the drain electrode include doping regions disposed in the channel layer.

In an embodiment of the semiconductor structure of the present invention, the source electrode includes a first conductive via connected to the first electrode, a second conductive via connected to the channel layer and a first circuit layer connecting the first conductive via and the second conductive via, and the drain electrode includes a third conductive via connected to the channel layer and a second circuit layer connected to the third conductive via.

The manufacturing method of the semiconductor structure of the present invention includes the following steps. A first electrode is formed on a substrate. An insulating layer is formed on the first electrode. A second electrode is formed on the insulating layer. A gate dielectric layer is formed on the second electrode. A channel layer is formed on the gate dielectric layer. A source electrode and a drain electrode are formed, wherein the source electrode is electrically connected to the first electrode and the channel layer, and the drain electrode is electrically connected to the channel layer.

In an embodiment of the manufacturing method of the semiconductor structure of the present invention, the second electrode and the insulating layer expose a portion of the first electrode.

In an embodiment of the manufacturing method of the semiconductor structure of the present invention, the channel layer and the gate dielectric layer expose a portion of the second electrode.

In an embodiment of the manufacturing method of the semiconductor structure of the present invention, a forming method of the first electrode, the insulating layer, the second electrode, the gate dielectric layer and the channel layer includes the following steps. A first electrode material layer, an insulating material layer, a second electrode material layer, a gate dielectric material layer and a channel material layer are formed in sequence on the substrate. A first patterning process is performed on the first electrode material layer, the insulating material layer, the second electrode material layer, the gate dielectric material layer and the channel material layer. A second patterning process is performed on the channel material layer, the gate dielectric material layer, the second electrode material layer and the insulating material layer. A third patterning process is performed on the channel material layer and the gate dielectric material layer.

In an embodiment of the manufacturing method of the semiconductor structure of the present invention, the manufacturing method further includes forming a cap layer to cover the first electrode, the insulating layer, the second electrode, the gate dielectric layer and the channel layer after forming the channel layer and before forming the source electrode and the drain electrode.

In an embodiment of the manufacturing method of the semiconductor structure of the present invention, the manufacturing method further includes forming a buffer layer on the substrate before forming the first electrode.

In an embodiment of the manufacturing method of the semiconductor structure of the present invention, the source electrode and the drain electrode are formed on the channel layer.

In an embodiment of the manufacturing method of the semiconductor structure of the present invention, the source electrode and the drain electrode include doped regions formed in the channel layer.

In an embodiment of the manufacturing method of the semiconductor structure of the present invention, the source electrode includes a first conductive via connected to the first electrode, a second conductive via connected to the channel layer and a first circuit layer connecting the first conductive via and the second conductive via, and the drain electrode includes a third conductive via connected to the channel layer and a second circuit layer connected to the third conductive via.

Based on the above, the semiconductor structure of the present invention includes a capacitor and a thin-film transistor stacked on the substrate, and the upper electrode of the capacitor may be used as the gate of the thin-film transistor. Therefore, the layout area occupied by the capacitor and the thin-film transistor may be effectively reduced, and the total thickness of the stacked capacitor and thin-film transistor may be effectively reduced.

### BRIEF DESCRIPTION OF THE DRAWINGS

FIGS. 1A to 1E are schematic cross-sectional views of the manufacturing process of the semiconductor structure of the first embodiment of the present invention.

FIG. 2 is a schematic cross-sectional view of the semiconductor structure of the second embodiment of the present invention.

FIG. 3 is a schematic cross-sectional view of the semiconductor structure of the third embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

In addition, “high dielectric constant (high-k) material” in the text may refer to a dielectric material with a dielectric constant greater than 4 in the present technical field.

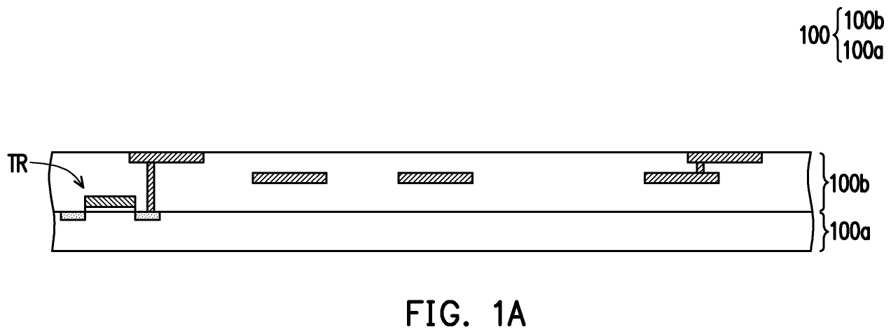

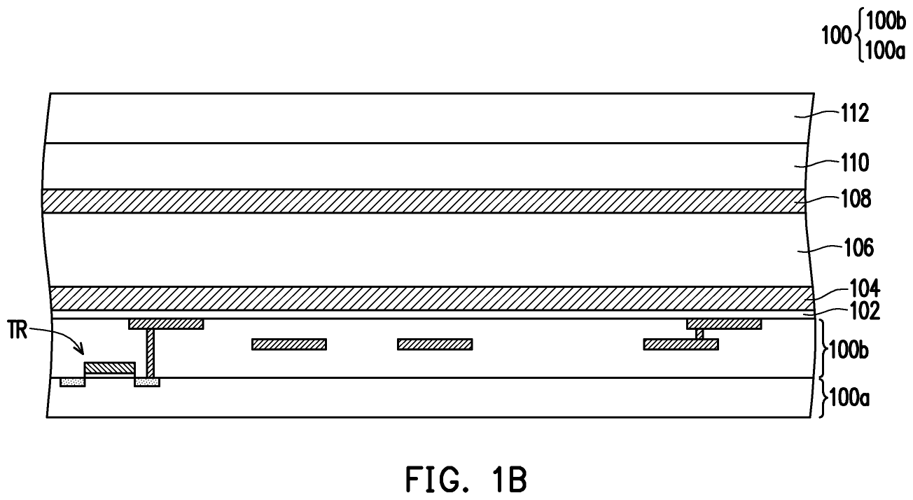

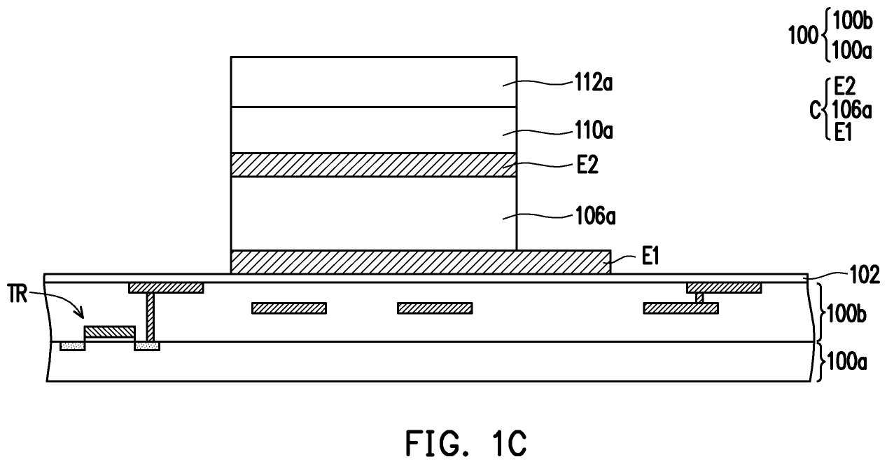

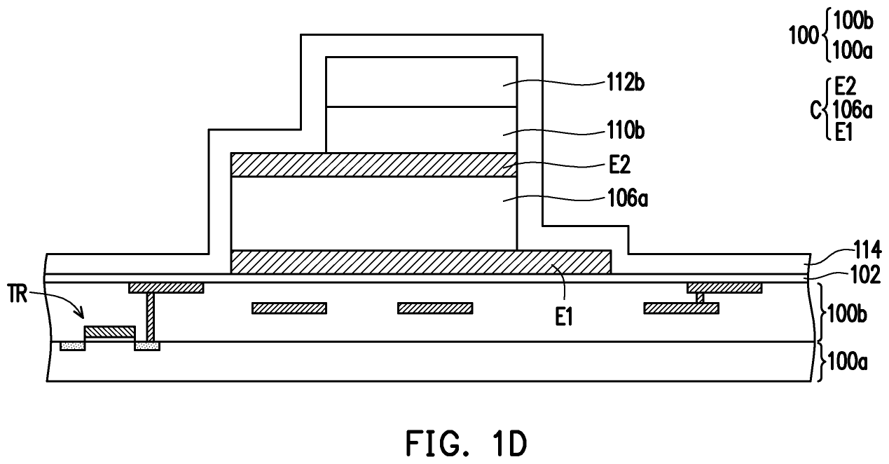

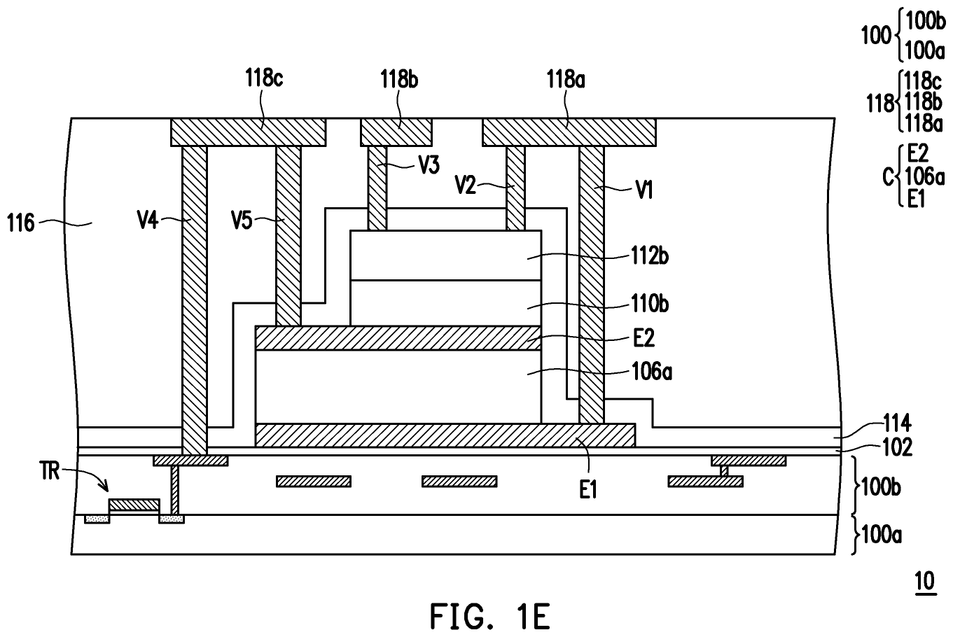

FIGS. 1A to 1E are schematic cross-sectional views of the manufacturing process of the semiconductor structure of the first embodiment of the present invention. In the present embodiment, the capacitor and the thin-film transistor are stacked on the substrate, and the upper electrode of the capacitor may be used as the gate of the thin-film transistor. In this way, the semiconductor structure of the present invention may include stacked capacitor and thin-film transistor, and may have a smaller layout area and a smaller thickness. The present embodiment will be described in detail below.

Referring to FIG. 1A, a substrate 100 is provided. In the present embodiment, the substrate 100 includes a silicon substrate 100a and an interconnect structure layer 100b located on the silicon substrate 100a. The silicon substrate 100a may be a silicon wafer. The interconnect structure layer 100b may include a dielectric layer, circuit layers and conductive vias connecting the circuit layers of different layers in the dielectric layer. The detailed configuration and forming method of the interconnect structure layer 100b are well known to those skilled in the art and will not be described further here. In addition, a transistor TR is disposed at the surface of the silicon substrate 100 and electrically connected with the interconnect structure layer 100b. In the present embodiment, the transistor TR may be a metal-oxide-semiconductor field effect transistor (MOSFET). In FIG. 1A, the structure of the interconnect structure layer 100b and the structure and quantity of the transistor TR are only exemplary, and the present invention is not limited thereto.

Referring to FIG. 1B, a buffer layer 102 may be formed on the substrate 100. In the present embodiment, the material of the buffer layer 102 is, for example, SiN, SiCN or SiON. Afterwards, a first electrode material layer 104, an insulating material layer 106, a second electrode material layer 108, a gate dielectric material layer 110 and a channel material layer 112 are sequentially formed on the buffer layer 102. In other embodies, the buffer layer 102 may be omitted depending on actual needs.

The first electrode material layer 104 is used to form the lower electrode of the capacitor. In the present embodiment, the first electrode material layer 104 may be a metal layer or a composite layer composed of a metal layer and a metal nitride layer, but the present invention is not limited thereto. For example, the first electrode material layer 104 is a titanium layer or a composite layer composed of a titanium layer and a titanium nitride layer.

The second electrode material layer 108 is used to form the upper electrode of the capacitor. The second electrode material layer 108 may be a metal layer or a composite layer composed of a metal layer and a metal nitride layer, but the present invention is not limited thereto. For example, the second electrode material layer 108 is a titanium layer or a composite layer composed of a titanium layer and a titanium nitride layer.

The insulating material layer 106 is used to form the insulator between the upper electrode and the lower electrode in the capacitor. The material of the insulating material layer 106 may be a dielectric material with high-k. For example, the insulating material layer 106 is a composite layer composed of a zirconium oxide (ZrO₂) layer, an aluminum oxide (Al₂O₃) layer and another zirconium oxide layer, but the present invention is not limited thereto.

The gate dielectric material layer 110 is used to form the gate dielectric layer in the thin-film transistor. In the present embodiment, the material of the gate dielectric material layer 110 is, for example, silicon oxide, but the present invention is not limited thereto. The channel material layer 112 is used to form the channel layer in the thin-film transistor. In the present embodiment, the material of the channel material layer 112 may be metal oxide. For example, the material of the channel material layer 112 is indium gallium zinc oxide (InGaZnO, IGZO), but the present invention is not limited thereto.

In addition, in the present embodiment, the capacitor and the thin-film transistor share a conductive layer as the electrode of the capacitor and the gate of the thin-film transistor. That is, in addition to forming the upper electrode of the capacitor, the second electrode material layer 108 is also used to form the gate of the thin-film transistor.

Referring to FIG. 1C, a first patterning process is performed on the first electrode material layer 104, the insulating material layer 106, the second electrode material layer 108, the gate dielectric material layer 110 and the channel material layer 112 to remove a part of the first electrode material layer 104, a part of the insulating material layer 106, a part of the second electrode material layer 108, a part of the gate dielectric material layer 110 and a part of the channel material layer 112 to define a region for forming a capacitor. After defining the region for forming the capacitor, a second patterning process is performed on the channel material layer 112, the gate dielectric material layer 110, the second electrode material layer 108 and the insulating material layer 106 to remove a part of the channel material layer 112, a part of the gate dielectric material layer 110, a part of the second electrode material layer 108 and a part of the insulating material layer 106.

In this way, a first electrode E1 formed by the first electrode material layer 104, an insulating layer 106a formed by the insulating material layer 106, a second electrode E2 formed by the second electrode material layer 108, a gate dielectric material layer 110a and a channel material layer 112a are formed on the substrate 100, and the channel material layer 112a, the gate dielectric material layer 110a, the second electrode E2 and the insulating layer 106a expose a portion of the first electrode E1. In the present embodiment, a portion of the first electrode E1 is exposed, but the present invention is not limited thereto. In other embodiments, some of the insulating material layer 106 may be remained on the exposed portion of the first electrode E1. The first electrode E1, the insulating layer 106a and the second electrode E2 may constitute a capacitor C with a metal-insulator-metal (MIM) configuration in the present embodiment.

Referring to FIG. 1D, a third patterning process is performed on the channel material layer 112a and the gate dielectric material layer 110a to remove a part of the channel material layer 112a and a part of the gate dielectric material layer 110a. In this way, a gate dielectric layer 110b formed by the gate dielectric material layer 110 and a channel layer 112b formed by the channel material layer 112 are formed on the capacitor C, and the channel layer 112b and the gate dielectric layer 110b expose a portion of the second electrode E2.

After forming the channel layer 112b and the gate dielectric layer 110b, a cap layer 114 may be formed on the substrate 100 to cover the first electrode E1, the insulating layer 106a, the second electrode E2, the gate dielectric layer 110b and the channel layer 112b. In the present embodiment, the material of the cap layer 114 is, for example, SiN, SiCN or SiON, but the present invention is not limited thereto. The cap layer 114 may be used to prevent the first electrode E1, the insulating layer 106a, the second electrode E2, the gate dielectric layer 110b and the channel layer 112b from being damaged in subsequent processes. In other embodiments, the cap layer 114 may be omitted depending on the actual needs.

Referring to FIG. 1E, a dielectric layer 116 is formed on the substrate 100. In the present embodiment, the dielectric layer 116 is formed on cap layer 114 to cover the first electrode E1, the insulating layer 106a, the second electrode E2, the gate dielectric layer 110b and the channel layer 112b. The dielectric layer 116 us used as an inter-metal dielectric (IMD) layer in the semiconductor structure of the present embodiment. The material of the dielectric layer 116 is, for example, silicon oxide, but the present invention is not limited thereto. For example, the material of the dielectric layer 116 may be phosphoric silicate glass (PSG) or undoped silicate glass (USG). After the dielectric layer 116 is formed, depending on actual deeds, a planarization process may be performed on the dielectric layer 116 to ensure that the dielectric layer 116 has a flat surface. The planarization process is, for example, a chemical mechanical polishing (CMP) process.

Then, a first conductive via V1, a second conductive via V2, a third conductive via V3, a fourth conductive via V4, a fifth conductive via V5, a first circuit layer 118a, a second circuit layer 118b and a third circuit layer 118c are formed in the dielectric layer 116. In the present embodiment, the first circuit layer 118a, the second circuit layer 118b and the third circuit layer 118c are located at the same level, that is, the first circuit layer 118a, the second circuit layer 118b and the third circuit layer 118c are the conductive layers on the same layer, but the present invention is not limited thereto. In other embodiments, the first circuit layer 118a, the second circuit layer 118b, and the third circuit layer 118c may be located at different levels.

The first conductive via V1 is connected to the first circuit layer 118a and extends downward through the cap layer 114 to be connected to the first electrode E1. The second conductive via V2 is connected to the first circuit layer 118a and extends downward through the cap layer 114 to connect to the channel layer 112b. Therefore, the channel layer 112b and the first electrode E1 may be electrically connected to each other through the first circuit layer 118a, the first conductive via V1 and the second conductive via V2.

The third conductive via V3 is connected to the second circuit layer 118b and extends downward through the cap layer 114 to connect to the channel layer 112b.

The fourth conductive via V4 is connected to the third circuit layer 118c and extends downward through the cap layer 114 and the buffer layer 102 to be connected to the circuit layer in the interconnect structure layer 100b. The fifth conductive via V5 is connected to the third circuit layer 118c and extends downward through the cap layer 114 to be connected to the second electrode E2. Therefore, the second electrode E2 and the transistor TR may be electrically connected to each other through the third circuit layer 118c, the fourth conductive via V4, the fifth conductive via V5 and the interconnect structure layer 100b.

In this way, a semiconductor structure 10 of the present embodiment is formed.

In the semiconductor structure 10 of the present embodiment, the first electrode E1, the insulating layer 106a and the second electrode E2 constitute a capacitor C having a metal-insulator-metal configuration. In addition, the second electrode E2, the gate dielectric layer 110b, the channel layer 112b, the first circuit layer 118a, the second circuit layer 118b, the first conductive via V1, the second conductive via V2 and the third conductive via V3 constituted a thin-film transistor, wherein the second electrode E2 may be used as the gate of the thin-film transistor, the first conductive via V1, the first circuit layer 118a and the second conductive via V2 may be used as the source electrode of the thin-film transistor, and the second circuit layer 118b and the third conductive via V3 may be used as the drain electrode of the thin-film transistor.

In the present embodiment, the thin-film transistor and capacitor C are stacked on the substrate 100, and the thin-film transistor and capacitor C share a conductive layer as their gate and upper electrode respectively. Therefore, the semiconductor structure 10 of the present embodiment may have a smaller layout area and a smaller thickness.

In addition, in the semiconductor structure 10 of the present embodiment, the thin-film transistor is electrically connected to the capacitor C through the first conductive via V1, the first circuit layer 118a and the second conductive via V2, and the capacitor C is electrically connected to the transistor TR through the fourth conductive via V4, the third circuit layer 118c, the fifth conductive via V5 and the interconnect structure layer 100b. Therefore, after voltages are applied to the gate and the drain electrode of the transistor TR and voltages are applied to the source electrode and drain electrode of the thin-film transistor, the thin-film transistor may be operated and the capacitance may be generated at the capacitor C.

In the present embodiment, the first conductive via V1, the first circuit layer 118a and the second conductive via V2 are used as the source electrode of the thin-film transistor, and the second circuit layer 118b and the third conductive via V3 are used as the drain electrode of the thin-film transistor, but the present invention is not limited thereto. In other embodiments, the thin-film transistor may have other types of source and drain electrodes.

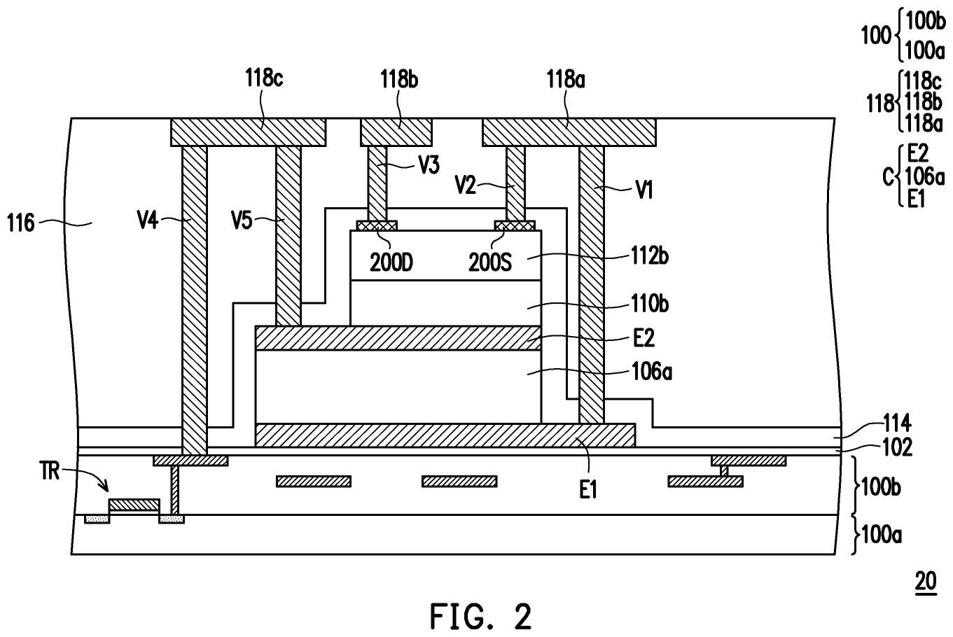

FIG. 2 is a schematic cross-sectional view of the semiconductor structure of the second embodiment of the present invention. In the present embodiment, the same components as in the first embodiment will be represented by the same reference symbols and will not be described again.

Referring to FIG. 2, in the semiconductor structure 20 of the present embodiment, a source electrode 200S and a drain electrode 200D are formed on the channel layer 112b and are separated from each other. The material of the source electrode 200S and the drain electrode 200D may be metal, but the present invention is not limited thereto.

In the present embodiment, the source electrode 200S may be electrically connected to the capacitor C through the first conductive via V1, the first circuit layer 118a and the second conductive via V2, and the drain electrode 200D may be connected to an external voltage source through the second circuit layer 118b and the third conductive via V3.

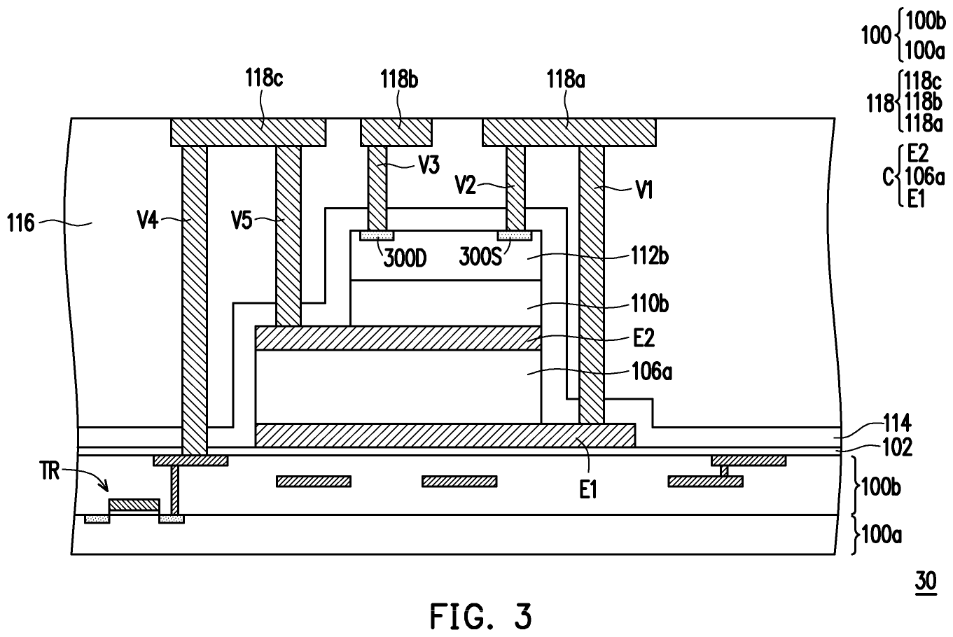

FIG. 3 is a schematic cross-sectional view of the semiconductor structure of the third embodiment of the present invention. In the present embodiment, the same components as in the first embodiment will be represented by the same reference symbols and will not be described again.

Referring to FIG. 3, in the semiconductor structure 30 of the present embodiment, two doped regions separated from each other are formed in the channel layer 112b to serve as a source electrode 300S and a drain electrode 300D respectively. The source electrode 300S and the drain electrode 300D are formed by, for example, performing an ion implantation process on the specific regions of the channel layer 112b.

In the present embodiment, the source electrode 300S may be electrically connected to the capacitor C through the first conductive via V1, the first circuit layer 118a and the second conductive via V2, and the drain electrode 300D may be connected to the external voltage source through the second circuit layer 118b and the third conductive via V3.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a first electrode, disposed on a substrate;
a second electrode, disposed on the first electrode;
an insulating layer, disposed between the first electrode and the second electrode;
a channel layer, disposed on the second electrode;
a gate dielectric layer, disposed between the channel layer and the second electrode;
a source electrode, electrically connected to the first electrode and the channel layer; and
a drain electrode, electrically connected to the channel layer.

2. The semiconductor structure of claim 1, wherein the second electrode and the insulating layer expose a portion of the first electrode.

3. The semiconductor structure of claim 1, wherein the channel layer and the gate dielectric layer expose a portion of the second electrode.

4. The semiconductor structure of claim 1, further comprising a cap layer covering the first electrode, the insulating layer, the second electrode, the gate dielectric layer and the channel layer.

5. The semiconductor structure of claim 4, wherein a material of the cap layer comprises silicon nitride (SiN), silicon carbonitride (SiCN) or silicon oxynitride (SiON).

6. The semiconductor structure of claim 1, wherein the second electrode is electrically connected to a transistor disposed at the substrate.

7. The semiconductor structure of claim 1, further comprising a buffer layer disposed between the substrate and the first electrode.

8. The semiconductor structure of claim 7, wherein a material of the buffer layer comprises SiN, SiCN or SiON.

9. The semiconductor structure of claim 1, wherein the source electrode and the drain electrode are disposed on the channel layer.

10. The semiconductor structure of claim 1, wherein the source electrode and the drain electrode comprise doping regions disposed in the channel layer.

11. The semiconductor structure of claim 1, wherein the source electrode comprises a first conductive via connected to the first electrode, a second conductive via connected to the channel layer and a first circuit layer connecting the first conductive via and the second conductive via, and the drain electrode comprises a third conductive via connected to the channel layer and a second circuit layer connected to the third conductive via.

12. A manufacturing method of a semiconductor structure, comprising:
forming a first electrode on a substrate;
forming an insulating layer on the first electrode;
forming a second electrode on the insulating layer;
forming a gate dielectric layer on the second electrode;
forming a channel layer on the gate dielectric layer; and
forming a source electrode and a drain electrode, wherein the source electrode is electrically connected to the first electrode and the channel layer, and the drain electrode is electrically connected to the channel layer.

13. The manufacturing method of claim 12, wherein the second electrode and the insulating layer expose a portion of the first electrode.

14. The manufacturing method of claim 12, wherein the channel layer and the gate dielectric layer expose a portion of the second electrode.

15. The manufacturing method of claim 12, wherein a forming method of the first electrode, the insulating layer, the second electrode, the gate dielectric layer and the channel layer comprises:
forming a first electrode material layer, an insulating material layer, a second electrode material layer, a gate dielectric material layer and a channel material layer in sequence on the substrate;
performing a first patterning process on the first electrode material layer, the insulating material layer, the second electrode material layer, the gate dielectric material layer and the channel material layer;
performing a second patterning process on the channel material layer, the gate dielectric material layer, the second electrode material layer and the insulating material layer; and
performing a third patterning process on the channel material layer and the gate dielectric material layer.

16. The manufacturing method of claim 12, further comprising forming a cap layer to cover the first electrode, the insulating layer, the second electrode, the gate dielectric layer and the channel layer after forming the channel layer and before forming the source electrode and the drain electrode.

17. The manufacturing method of claim 12, further comprising forming a buffer layer on the substrate before forming the first electrode.

18. The manufacturing method of claim 12, wherein the source electrode and the drain electrode are formed on the channel layer.

19. The manufacturing method of claim 12, wherein the source electrode and the drain electrode comprise doped regions formed in the channel layer.

20. The manufacturing method of claim 12, wherein the source electrode comprises a first conductive via connected to the first electrode, a second conductive via connected to the channel layer and a first circuit layer connecting the first conductive via and the second conductive via, and the drain electrode comprises a third conductive via connected to the channel layer and a second circuit layer connected to the third conductive via.
